(19) United States
(12) Patent Application Publication
(10) Pub. No.: US 2011/0156134 A1
(43) Pub. Date: Jun. 30, 2011

(54) METHOD OF FABRICATING SEMICONDUCTOR DEVICE AND SEMICONDUCTOR DEVICE FABRICATED THEREBY

(75) Inventor: Jae Young KIM, Cheongju (KR)

(73) Assignee: Hynix Semiconductor Inc., Icheon (KR)

(21) Appl. No.: 12/840,096

(22) Filed: Jul. 20, 2010

(30) Foreign Application Priority Data
Dec. 29, 2009 (KR) 10-2009-0132667

(51) Int. Cl. H01L 29/78; H01L 21/336

(52) U.S. Cl. 257/329; 438/268; 257/E29.257; 257/E21.41

(57) ABSTRACT

The present invention is for weakening an electric field between a gate and a drain and preventing an electronic short between them. An embodiment of the present invention provides a method for manufacturing a semiconductor device, comprising forming a highly doped region in a semiconductor substrate through a first ion implantation process, forming a lightly doped region over the highly doped region through a second ion implantation process, forming a vertical transistor including the lightly doped region and a channel region having a pillar shape over the lightly doped region.

### CROSS-REFERENCE TO RELATED APPLICATION

Priority is claimed to Korean patent application number 10-2009-0132667, filed on Dec. 29, 2009, which is incorporated by reference in its entirety.

### FIELD OF THE INVENTION

The present invention relates to a method of manufacturing a semiconductor device of high integration, and more specifically, to a method for increasing integration of the semiconductor device including a vertical-type transistor and improving operational reliability and yield of the semiconductor device.

### BACKGROUND OF THE INVENTION

Generally, a semiconductor is a material with both properties as a conductor and a non-conductor. The semiconductor works like a nonconductor in a pure state, but addition of impurities or other manipulation can increase the electric conductivity of the semiconductor. Impurities are added to the semiconductor to form a semiconductor device such as a transistor. A semiconductor memory apparatus is one example of such a semiconductor device.

A type of semiconductor memory apparatus includes a plurality of unit cells each including a capacitor and a transistor. A double-capacitor has been used to temporarily store data. A transistor has been used to transmit data between a bit line and a capacitor in response to a control signal (word line) using electric conductivity of the semiconductor that changes depending on environment. The transistor has three regions including a gate, a source and a drain, and charges between the source and drain move in response to a control signal inputted to the gate. The charges between the source and the drain move through a channel region.

To form a transistor in a semiconductor substrate, a gate is formed in the semiconductor substrate, and impurities are doped at both sides of the gate to form a source and a drain. In this case, a region under the gate may be used as a channel electrically connecting the source to the drain. If the channel is formed on one horizontal plane, the transistor occupies a large region in the semiconductor substrate because the channel is required to have a minimum length in order to prevent a short channel effect. A long channel increases the chip size and thus limits the total number of chips per wafer.

If the size of each semiconductor chip is decreased, the total number of semiconductor chips fabricated from a single wafer could be increased so that productivity is improved. For this purpose, many suggestions have been made for reducing the area of the semiconductor chip. One method uses a vertical transistor including a vertical channel instead of a horizontally plane channel.

When the vertical transistor is applied, an area of unit cell can be decreased up to 4F². Herein, F means a minimum pattern size allowed under a given design rule. In the case that the vertical transistor is applied as a cell transistor, a capacitor may be formed over the vertical transistor and a bit line may be buried in the semiconductor substrate. A word line coupled to a gate of the cell transistor is configured to wrap a pillar pattern over the bit line.

Under this structure, it is likely that the bit line and the word line are electrically short. Compared with a conventional transistor whose body is formed of a wide and thick semiconductor substrate, the body of the vertical transistor is formed of a tiny and narrow pillar. Thus, the vertical transistor is susceptible to a punch-through phenomenon, floating body effect, and so on.

To overcome the above mentioned disadvantages, an ion implantation process is performed to form a highly doped region in the tiny and narrow pillar. However, dopants implanted by the ion implantation process can increase an electric field and a threshold voltage so that performance and operational reliability of a cell transistor are impaired. Further, in the case that a bit line is formed by an ion implantation process for implanting dopants into a semiconductor substrate under the tiny and narrow pillar, dopants can also be implanted into the sidewalls of the tiny and narrow pillar. Accordingly, an electric short between a bit line formed by the ion implantation process and a word line wrapping the sidewalls of the pillar may occur.

### SUMMARY OF THE INVENTION

An embodiment of the present invention is directed to a semiconductor device and a method for manufacturing the semiconductor device, which is configured to weaken an electric field between a gate and a drain and prevent an electronic short between them, by forming a lightly doped region in the drain through the ion implantation process so that operational reliability and performance are improved.

In accordance with an embodiment of the present invention, a method for manufacturing a semiconductor apparatus, comprising forming a highly doped region in a semiconductor substrate through a first ion implantation process, forming a lightly doped region over the highly doped region through a second ion implantation process, forming a vertical transistor including the lightly doped region and a channel region having a pillar shape over the lightly doped region.

The first ion implantation process may inject dopants including one of boron-ion series into the semiconductor substrate. The second ion implantation process may inject dopants including a carbon. The second ion implantation process can be performed with implantation energy of less than 1E14 (P⁺/cm²).

The lightly doped region may be formed in a thickness of about 50 Å. The channel region and one of source/drain regions included in the vertical transistor may be formed between a top of the semiconductor substrate and the highly doped region.

The process for forming a highly doped region may comprise forming a trench in the semiconductor substrate and injecting dopants into a region which is deep of the channel region from a bottom of the trench.

The process for forming a vertical transistor may comprise depositing a hard mask layer in the trench, forming a upper pillar pattern through etching the semiconductor substrate by using the hard mask layer as an etch mask, forming a space at sidewalls of the upper pillar pattern, performing an anisotropy etching process on the semiconductor substrate by using the space as an etch mask to form a lower pillar pattern which is narrower than the upper pillar pattern, forming a bit line between pillars having the upper pillar pattern and the lower pillar pattern over the semiconductor substrate, removing the space and forming a gate oxide layer surrounding the upper pillar pattern and the lower pillar pattern, forming a gate surrounding the gate oxide layer, forming an insulating layer between the pillars.

The method for manufacturing a semiconductor apparatus may further comprise a capacitor coupled to the upper pillar pattern.

The lower pillar pattern can be formed up to a depth of the lightly doped region. The bit line may be formed by implanting an ion between the highly doped region and a neighboring highly doped region over the semiconductor substrate. The upper pillar pattern can be formed in a depth of 1500 to 2000 Å from a top of the semiconductor substrate.

A semiconductor apparatus manufactured by a method for manufacturing a semiconductor apparatus, comprising forming a highly doped region in a semiconductor substrate through a first ion implantation process, forming a lightly doped region over the highly doped region through a second ion implantation process, forming a vertical transistor including the lightly doped region and a channel region having a pillar shape over the lightly doped region, wherein source/drain regions are located on/under the channel region.

The lightly doped region comprising a carbon may be formed in a thickness of about 50 Å. The highly doped region may comprise one of boron ion (B+) series.

### BRIEF DESCRIPTION OF THE DRAWINGS

FIGS. 1a to 1g are cross-sectional views showing a method for manufacturing a semiconductor device including a vertical transistor in accordance with an embodiment of the present invention.

FIG. 2 is a graph showing ion concentration of the vertical transistor manufactured by the method shown in FIGS. 1a to 1g.

FIG. 3 is a graph showing a threshold voltage of the vertical transistor manufactured by the method shown in FIGS. 1a to 1g.

### DESCRIPTION OF SPECIFIC EMBODIMENTS

Embodiments of the present invention will be described below in more detail with reference to the accompanying drawings. The present invention may, however, be embodied in different forms and should not be limited to the embodiments set forth herein. Throughout the disclosure, like reference numerals refer to like parts throughout the various figures and embodiments of the present invention.

An embodiment of the present invention illustrates a semiconductor apparatus including a vertical transistor. In particular, to prevent an electric short between a gate and a drain, the drain and a non-conductive region is fabricated before a channel of the transistor is formed. The gate is then subsequently formed. Hereinafter, embodiments of the present invention are described with reference to the accompanying drawings.

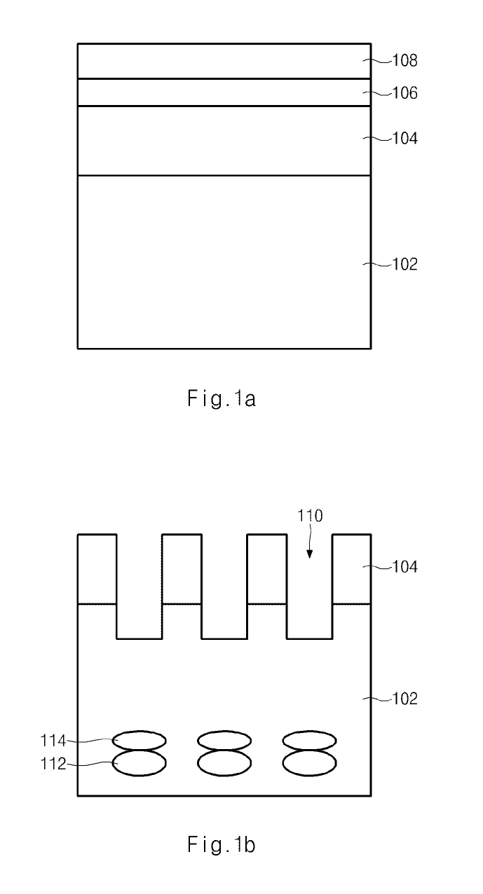

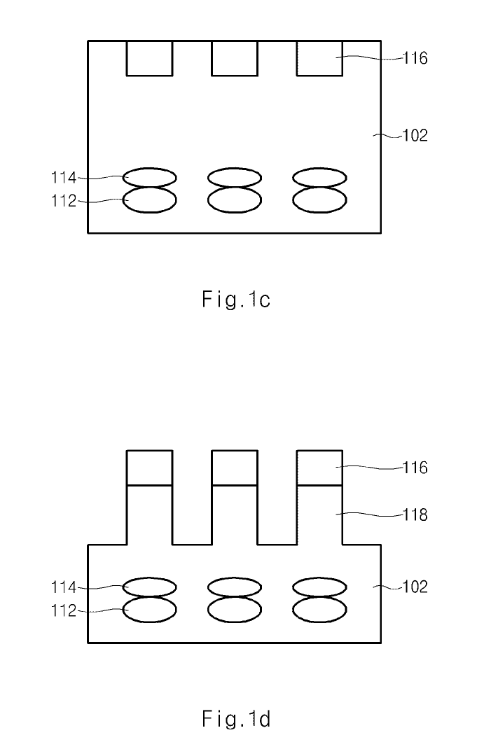

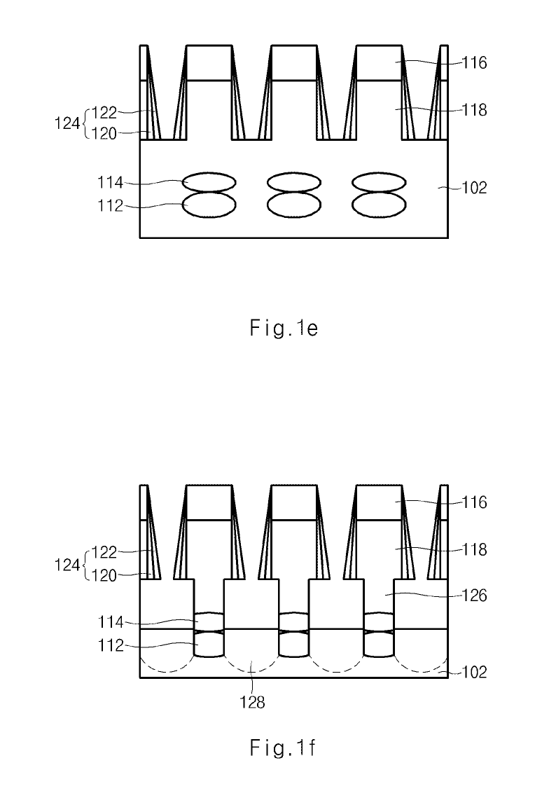

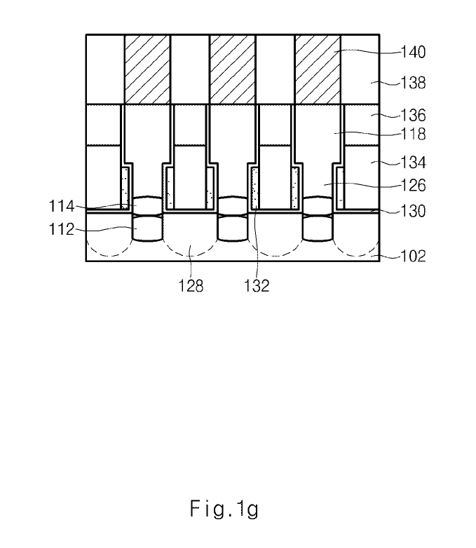

FIGS. 1a to 1g are cross-sectional views showing a method for manufacturing a semiconductor device including a vertical transistor in accordance with an embodiment of the present invention.

Referring to FIG. 1a, in order to form a vertical transistor, a first hard mask layer 104 is deposited over a semiconductor substrate 102 including a silicon Si. Over the first hard mask layer 104, an anti-reflection layer 106 and a photo-resist layer 108 are deposited.

Referring to FIG. 1b, the photo-resist layer 108 is patterned by a lithography process using a mask configured to define a channel region. Then, by using the patterned photo-resist layer 108 as an etching mask, the anti-reflection layer 106 and the first hard mask layer 104 are etched. After the remaining photo-resist layer 108 and anti-reflection layer 106 are removed, the semiconductor substrate 102 is etched by using the patterned first hard mask layer 104 as a mask to generate a trench 110. Herein, the depth of the trench 110 is about 1500 Å or less.

A first ion implantation process for implanting dopants into the semiconductor substrate 102 exposed by the trench 110 is performed to form a highly doped region 112. Herein, the highly doped region 112 is formed to a predetermined depth from the bottom of the trench 112. For example, if a source/drain region is formed to a depth of 1500 to 2000 Å from a top surface of the semiconductor substrate 102, the highly doped region 112 is formed deeper than a gate region of 2000 Å.

After the first ion implantation process, a second ion implantation process for implanting carbon atoms into the semiconductor substrate 102 is performed to form a lightly doped region 114. Herein, in the second ion implantation process, preferably, implantation energy of less than 1E14 (P⁺/cm²) is used. In an embodiment, the lightly doped region 114 configured to prevent a diffusion of dopants in the highly doped region 112 is located in a depth between the highly doped region 112 and the gate region and formed to have a thickness (or vertical extension) of about 50 Å.

Referring to FIG. 1c, a second hard mask layer 116 is deposited over the trench 110, and a planarization process such as CMP is performed until the semiconductor substrate 202 is exposed.

Referring to FIG. 1d, the exposed semiconductor substrate 202 is etched by using the second hard mask layer 116 as an etching mask. In this embodiment, the semiconductor substrate 202 is etched about 2000 Å deep to form an upper pillar pattern 118 having a height of about 500 Å. Herein, since the bottom of the trench 110 becomes a top of the upper pillar pattern 118, the base of the upper pillar pattern 118 is located at a depth of about 1500 to 2000 Å from the top surface of the second hard mask layer 116.

Referring to FIG. 1e, a space oxide layer 120 and a space nitride layer 122 are deposited over the upper pillar pattern 118 and the semiconductor substrate 102. Then, an etch-back process is performed so that a portion of the semiconductor substrate 102 between the upper pillar patterns 118 is exposed and a spacer 124 is formed on the sidewalls of the upper pillar patterns 118.

Referring to FIG. 1f, an anisotropic etching process is performed to the exposed semiconductor substrate 102 between the upper pillar patterns 118. Through the anisotropic etching process, a lower pillar pattern 126 is formed under the upper pillar pattern 118. Herein, the base of the lower pillar pattern 126 may extend down to the highly doped region 112. Furthermore, a width or a diameter of the lower pillar pattern 126 is narrower than that of the upper pillar pattern 118.

To form a bit line 128, an ion implantation process is performed to the semiconductor substrate 102 exposed between pillars, each including the lower pillar pattern 126 and the upper pillar pattern 118. Though not shown, a process may be performed additionally for separating the bit line 128 at a location crossed by a word line.

Referring to FIG. 1g, after the spacer 124 at the sidewalls of the upper pillar pattern 118 is removed; a gate oxide layer 130 is formed over the exposed semiconductor substrate 102, the lower pillar pattern 126, and the upper pillar pattern 118. Then, a gate electrode 132 is formed so as to surround the lower pillar pattern 126. Though not shown, a word line may be formed between the gate electrodes 132 in a direction crossing the bit line 128.

In a space remained between neighboring gate electrodes 132, an inter-layer insulating layer 134 is deposited. A third hard mask layer 136 is formed over the inter-layer insulating layer 134 and planarized until a top surface of the upper pillar pattern 118 is exposed. Over the upper pillar pattern 118, an insulting layer 138 is formed; then, a contact hole (not shown) exposing the upper pillar pattern 118 is formed by etching the insulating layer 138. Over the contact hole, a capacitor 140 comprising a lower electrode, a dielectric layer, and an upper electrode is formed.

As above described, according to a method for manufacturing a semiconductor device in accordance with an embodiment of the present invention, a highly doped region is formed at a predetermined depth in a semiconductor substrate and a lightly doped region is formed over the highly doped region. Then, a pillar used as a channel region of a vertical transistor is formed to substantially the same height as the depth of the lightly doped region. The lightly doped region formed by implanting a carbon into the semiconductor substrate suppresses diffusion of dopants in the highly doped region while charge is supplied. Thus, an embodiment of the present invention may restrain a reverse short channel effect (RSCE) caused by non-uniform ion density of the channel region and diffusion of the highly doped region and prevent the threshold voltage of a vertical transistor from increasing. Further, the lightly doped region provided over the highly doped region can prevent a gate and a drain of the vertical transistor from overlapping, and thus causing an electrical short.

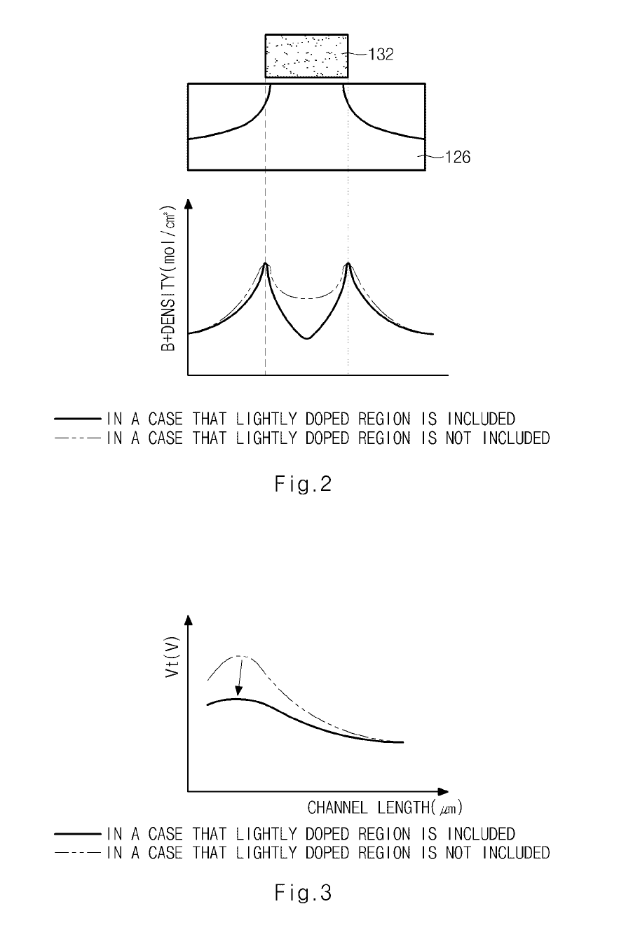

FIG. 2 is a graph showing ion concentration of the vertical transistor manufactured by the method shown in FIGS. 1a to 1g. Particularly, FIG. 2 depicts a source, a gate, and a drain of a vertical transistor and a dopant (B+) density of each region.

As shown, the dopant densities at junctions between the gate and the source and between the gate and the drain are higher than those under the gate, the source, the drain. In a case that a lightly doped region is provided according to an embodiment of the present invention, the dopant density under the gate is lower than that when a lightly doped region is not provided.

In a conventional transistor (having no lightly doped region formed by implanting a carbon), dopant density under the gate is set higher than those under the source and the drain in order to prevent a short channel effect such as a punch-through phenomenon. However, higher dopant density in the channel region under the gate may increase an electric field and cause a reverse short channel effect (RSCE) by increasing a threshold voltage.

However, in an embodiment of the present invention, the lightly doped region may decrease in dopant density in the channel region as the dopant densities at junctions between the gate and the source and between the gate and the drain are still kept high, thus suppressing a reverse short channel effect (RSCE).

FIG. 3 is a graph showing a threshold voltage of the vertical transistor manufactured by the method shown in FIGS. 1a to 1g. As shown, a lightly doped region formed through a second ion-implantation process using carbon into a semiconductor substrate keeps stable the threshold voltage Vt of the vertical transistor. As compared with a conventional transistor with no lightly doped region, a transistor with the lightly doped region may reduce a level of the threshold voltage Vt. Thus, an embodiment of the present invention can provide a vertical transistor having an improved threshold voltage level uniformity regardless of channel length.

A semiconductor apparatus manufactured by a method according to an embodiment of the present invention may prevent a short channel effect, such as a punch-through phenomenon, a floating body effect, and so on, through a highly doped region injected by a dopant (B+), and suppress a reverse short channel effect, e.g., increase of electric field and threshold voltage as well, through a lightly doped region implanted by a carbon. Further, the highly doped region and lightly doped region of the semiconductor apparatus can prevent an electrical short between a gate and a drain of a vertical transistor and increasing the electric field can improve the operational reliability.

In the present invention, after a highly doped region is formed, a lightly doped region is formed over the highly doped region and a channel region having a vertical pillar shape is formed over the lightly doped region. Accordingly, a gate of a vertical transistor may be electrically separated from a drain of the vertical transistor.

While the present invention has been described with respect to the specific embodiments, it will be apparent to those skilled in the art that various changes and modifications may be made without departing from the spirit and scope of the invention as defined in the following claims.

What is claimed is:

1. A method for manufacturing a semiconductor device, the method comprising:
forming a pillar pattern in a substrate to form a vertical transistor;
forming a first doped region below the pillar pattern; and
forming a second doped region at a lower part of the pillar pattern above the first doped region, the first doped region having a higher dopant concentration than that of the second doped region.

2. The method according to claim 1, wherein the step of forming the first doped region comprising:
performing an ion implantation process using boron-ions.

3. The method according to claim 1, wherein the step of forming the second doped region comprises:
performing an ion implantation process using carbon ions.

4. The method according to claim 1, wherein the step of forming the first doped region comprising:
performing an ion implantation process with implantation energy of no more than 1E14 (P⁺/cm²).

5. The method according to claim 1, wherein the second doped region has a vertical extension of about 50 Å.

6. The method according to claim 1, further comprising:
forming a third doped region over the pillar pattern, the third doped region having a dopant concentration that is greater than that of the second doped region; and
forming a gate pattern over a sidewall of the pillar pattern.

7. The method according to claim 1, wherein the step of forming the first doped region comprises:
forming a trench in the substrate; and
implanting dopants below the trench.

8. A method for manufacturing a semiconductor device, the method comprising:
forming a first trench in a substrate;
performing a first ion implantation process to form a first highly-doped region in the substrate below the first trench;
performing a second ion implantation process to form a lightly-doped region in the substrate above the first highly-doped region;
patterning the substrate to form a pillar pattern over the lightly-doped region;
forming a gate oxide layer over a sidewall of the pillar pattern;
forming a gate over the gate oxide layer;
forming a second highly-doped region over the pillar pattern.

9. The method according to claim 8, the first and the second highly-doped regions serve as a drain and a source, respectively.

10. The method according to claim 8, further comprising:
forming a bit line adjacent to the first highly doped region through an ion implantation process.

11. The method according to claim 10, wherein a channel is formed between the second highly-doped region and the first highly-doped region through the lightly-dope region.

12. The method according to claim 8, wherein the first trench is formed in a depth of 1500 to 2000 Å from a top of the substrate.

13. A semiconductor device comprising:
a pillar pattern formed in a substrate;
a first highly-doped region formed below the pillar pattern; and
a lightly-doped region formed at a lower part of the pillar pattern above the highly-doped drain.

14. The semiconductor device according to claim 13, wherein the lightly-doped region comprising carbon.

15. The semiconductor device according to claim 13, wherein the first highly-doped region comprises boron ions (B).

16. The semiconductor device according to claim 13, further comprising:
a second highly-doped region formed over the pillar pattern; and
a gate pattern formed over a sidewall of the pillar pattern.

17. The semiconductor device according to claim 13, wherein the gate pattern is configured to surround the pillar pattern.
